(19) United States
(12) Patent Application Publication
(10) Pub. No.: US 2006/0289836 A1
(43) Pub. Date: Dec. 28, 2006

(54) Precursor wire of Nb-Sn phase superconducting wire

(75) Inventors: Kunihiko Egawa, Tokyo (JP); Yoshio Kubo, Tokyo (JP); Takayuki Nagai, Tokyo (JP); Takanori Sone, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 11/156,590

(22) Filed: Jun. 21, 2005

(30) Foreign Application Priority Data
Aug. 27, 2004 (JP) 2004-248614

(51) Int. Cl. H01L 39/24

(52) U.S. Cl. 252/500; 505/230

(57) ABSTRACT

A precursor wire for the Nb—Sn phase superconducting wire includes a structure having a plurality of modules each composed by arranging a Sn-based metal core in a Cu-based metal matrix and the Nb-based metal filaments concentrically around the core is obtained by adjusting the amount of the Sn-based metal cores in each module to form the boundaries of the ε-phase bronze layers to be formed by reaction of Sn of the Sn-based metal cores and Cu-based metal matrix by the heat-treatment in the range including all of or a ratio of approximately not lower than 0.08 and not more than 0.32 of the existence region the Nb-based metal filaments.

### BACKGROUND OF THE INVENTION

1. Field of the Invention

The invention relates to a precursor wire of a Nb—Sn phase superconducting wire to be a Nb₃Sn superconducting wire by heating which has a high critical current density (J_{c}) property and suppressed increase of hysteresis loss (Qₕ) property.

2. Description of the Related Art

To realize a large scale superconductor coil for nuclear fusion, it is indispensable to develop a superconducting wire having a high critical current density (J_{c}) property and a low hysteresis loss (Qₕ) property and particularly, for a toroidal coil for magnetic fields, a Nb₃Sn superconducting wire is used. For its stabilization, a superconducting wire is required to have a structure composed by embedding a large number of superconducting filaments with a diameter of several 10 μm or smaller in a matrix of a metal such as Cu with a low resistivity and called as an ultra-fine multifilamentary wire. The precursor wire of the Nb₃Sn superconducting wire has a structure composed by embedding a large number of Sn-based metal cores and Nb-based metal filaments in a Cu-based metal matrix and heat-treatment of the wire after drawing process causes diffusions of the Sn-based metal cores of the wire in the Cu-based matrix and also in the Nb-based metal filaments and accordingly produces Nb₃Sn in the surrounding of the Nb-based metal filaments or in the whole body to obtain a Nb₃Sn superconducting wire.

With respect to a precursor wire of a conventional Nb₃Sn superconducting wire, in the above-mentioned heat-treatment process, the Sn-based metal cores are diffused in the surrounding Cu-based metal matrix so that an ε-phase bronze layer (Cu₃Sn) is formed and in the boundary (the outer edge) region of the ε-phase bronze layer, the Nb₃Sn filaments are in contact with the layer to result in a problem of increase Of Qₕ.

For improvement of the problem, there have been proposed some techniques of suppressing increase of Qₕ by arranging the Nb-based metal filaments in precursor wire in such a manner that the Nb₃Sn filament spacing is wider in the boundary region of the ε-phase bronze layer than those in other regions. (Reference to Japanese Patent No. 3012436 (page 3, FIG. 2).

### SUMMARY OF THE INVENTION

The cause of the increase of Qₕ property of a superconducting wire is mutual contact of Nb₃Sn filaments caused by heat-treatment and it has been understood that the mutual contact of the Nb₃Sn filaments is caused in the boundary periphery of a region in which the Sn-based metal cores arranged in the center part of the precursor wire and the Cu-based metal matrix are alloyed and form the ε-phase bronze layer by heat-treatment. In the precursor wire of the conventional Nb₃Sn superconducting wire disclosed in the Japanese Patent No. 3012436 (page 3, FIG. 2), to prevent the mutual contact of the Nb₃Sn filaments, which is a cause of the increase of Qₕ property in form of a superconducting wire, caused by heat-treatment, it is required to keep the intervals of the Nb-based metal filaments to be embedded in the Cu-based metal matrix wide in the boundary periphery of the region where the ε-phase bronze layer is to be formed. More practically, since the boundary of the ε-phase bronze layer is to be formed between the Nb-based metal filaments in the third and fourth layers from the center, the diameter of each Nb-based metal filament in the third to fifth layers is made slightly thin and thus the filament spacing after the drawing process are slightly widened as described above. As a result, the amount of the Nb-based metal filaments embedded in the Cu-based metal matrix is limited and J_{c} property of the superconducting wire obtained by heating the precursor wire is at highest 800 A/mm² at a temperature of 4.2 K in a magnetic field of 12 T and thus there remains a problem that it is impossible to obtain a wire having further higher J_{c} property.

This invention has been accomplished to solve the above-mentioned problems and aims to provide a precursor wire of a Nb—Sn phase superconducting wire to be a Nb₃Sn superconducting wire by heat-treatment which has a high J_{c} property and a suppressed increase of Qₕ property.

A precursor wire of the Nb—Sn phase superconducting wire according to the invention is heated to produce the superconducting wire, and elongates in the longitudinal direction. The precursor wire includes a plurality of modules having a cross section including a core part and a shell part surrounding of the core part. Each of modules includes:

a core part made of only Sn-based metal; and

a shell part including:
a matrix made of a Cu-based metal; and
Nb-based metal filaments embedded in the Cu-based metal,
   wherein the Nb-based metal filaments are arranged at equal intervals concentrically around the core part and further around the circumferences of Nb-based metal filaments sequentially toward the outer circumference, and

wherein, in each of modules, the amount of the Sn-based metal of the core part is so adjusted as to form an area defined by the boundaries of the ε-phase bronze layers, which are formed in the module by reaction of the Sn-based metal of the core part and Cu-based metal of the matrix by the heat-treatment, so that the area includes all of the Nb-based metal filaments in the module.

Further, the precursor wire is characterized in that the volume ratio of the Nb-based metal filaments occupying in each of the modules is approximately not lower than 0.28 and not more than 0.34: the volume ratio of the ε-phase bronze layer to the Cu-based metal matrix in each module is approximately not lower than 0.6 and not more than 0.8: the diameter of each Nb-based metal filament is approximately not thinner than 1 μm and not thicker than 5 μm: and the intervals of the Nb-based metal filaments are approximately not narrower than 0.7 μm and not wider than 1.5 μm.

Another precursor wire of the invention is characterized in that the amount of the Sn-based metal cores is so adjusted as to form the boundaries of the ε-phase bronze layers to be formed in the modules by reaction of the Sn-based metal cores and the Cu-based metal matrix by heat-treatment in the range including a ratio of approximately not lower than 0.05 and not more than 0.35 of the existence region of the Nb-based metal filaments.

Further, the precursor wire is characterized in that: the volume ratio of the Nb-based metal filaments occupying in each of the modules is approximately not lower than 0.23 and not more than 0.27; the volume ratio of the ε-phase bronze layer to the Cu-based metal matrix in each module is approximately not lower than 0.4 and not more than 0.55; the diameter of each Nb-based metal filament is approximately not thinner than 1 μm and not thicker than 5 μm; and the intervals of the Nb-based metal filaments are approximately not narrower than 0.7 μm and not wider than 1.5 μm.

Accordingly to the invention, since the precursor wire of a Nb—Sn phase superconducting wire is so composed as to have the characteristics that the wire comprises a plurality of modules each composed by embedding Nb-based metal filaments and a Sn-based metal core in a Cu-based metal matrix: that each module has a structure formed by arranging the Sn-based metal core in the center part of the module, arranging the Nb-based metal filaments at equal intervals concentrically around the core and further around the circumferences of Nb-based metal filaments sequentially toward the outer circumference: and that the amount of the Sn-based metal cores is so adjusted as to form the boundaries of the ε-phase bronze layers to be formed in the modules by reaction of the Sn-based metal cores and the Cu-based metal matrix by heat-treatment in the range including all of the Nb-based metal filaments, the above-mentioned boundaries of the ε-phase bronze layer regions are outside of the existence region of the Nb-based metal filaments to prevent mutual contact of the Nb₃Sn filaments, which is a cause of increase of Qₕ property and thus provide the precursor wire of a Nb—Sn phase superconducting wire with suppressed increase Of Qₕ property. Further, according to the invention, because of the same reason, it is made no need to keep the intervals of the Nb-based metal filaments wide for suppressing the increase of Qₕ property, that is, the amount of the Nb-based metal filaments is not limited and therefore, the amount of the Nb₃Sn filaments in the superconducting wire obtained by heat-treatment of the precursor wire is assured and thus a precursor wire of a Nb—Sn phase superconducting wire having a high J_{c} property can be obtained.

In the above-mentioned precursor wire according to invention, since the volume ratio of the Nb-based metal filaments occupying in each of the modules is approximately not lower than 0.28 and not more than 0.34; the volume ratio of the ε-phase bronze layer to the Cu-based metal matrix in each module is approximately not lower than 0.6 and not more than 0.8; the diameter of each Nb-based metal filament is approximately not thinner than 1 μm and not thicker than 5 μm; and the intervals of the Nb-based metal filaments are approximately not narrower than 0.7 μm and not wider than 1.5 μm, the above-mentioned boundaries of the ε-phase bronze layers are outside of the existence region of the Nb₃Sn filaments to prevent mutual bonding of the Nb-based metal filaments and further the amount of Nb to form the Nb₃Sn filaments is assured to be high and thus a precursor wire of a Nb—Sn phase superconducting wire having a high J_{c} property and a low Qₕ property can be obtained.

Further, in another precursor wire according to the invention, since the precursor wire is so composed as to have the characteristics that the amount of the Sn-based metal cores is so adjusted as to form the boundaries of the ε-phase bronze layers to be formed in the modules by reaction of the Sn-based metal cores and the Cu-based metal matrix by heat-treatment in the range including a ratio of approximately not lower than 0.05 and not more than 0.35 of the existence region the Nb-based metal filaments, the mutual contact region of the Nb₃Sn filaments can be limited to be narrow in the superconducting wire obtained by heat-treatment of the precursor wire and thus a precursor wire of Nb—Sn phase superconducting wire with suppressed increase of Qₕ property can be obtained. Further, because of the same reason, it is made no need to keep the intervals of the Nb-based metal filaments wide for suppressing the increase of Qₕ property, that is, the amount of the Nb-based metal filaments is not limited and therefore, the amount of the Nb₃Sn filaments in the superconducting wire obtained by heat-treatment of the precursor wire is assured and thus a precursor wire of a Nb—Sn phase superconducting wire having a high J_{c} property can be obtained.

In the above-mentioned precursor wire according to invention, since the volume ratio of the Nb-based metal filaments occupying in each of the modules is approximately not lower than 0.23 and not more than 0.27; the volume ratio of the ε-phase bronze layer to the Cu-based metal matrix in each module is approximately not lower than 0.4 and not more than 0.55; the diameter of each Nb-based metal filament is approximately not thinner than 1 μm and not thicker than 5 μm; and the intervals of the Nb-based metal filaments are approximately not narrower than 0.7 μm and not wider than 1.5 μm, the above-mentioned boundaries of the ε-phase bronze layers includes a ratio of approximately not lower than 0.05 and not more than 0.35 of the existence region the Nb-based metal filaments and mutual bonding of the Nb₃Sn filaments is suppressed to the minimum and the amount of Nb to form the Nb₃Sn filaments is assured to be high and thus a precursor wire of a Nb—Sn phase superconducting wire having a high J_{c} property and a low Qₕ property can be obtained.

### BRIEF DESCRIPTION OF THE DRAWINGS

The present invention will become readily understood from the following description of preferred embodiments thereof made with reference to the accompanying drawings, in which like parts are designated by like reference numeral, and in which:

FIG. 1 is a cross-sectional view of a precursor wire of a Nb—Sn phase superconducting wire according to an embodiment 1 of the invention;

FIG. 2 is a cross-sectional view of a composite billet according to the embodiment 1 of the invention;

FIG. 3 is a graph illustrating the J_{c} property measured in a magnetic field of 12 T in liquid helium and Qₕ property measured in a magnetic field for ±13 T cycle in liquid helium of the precursor wire of the Nb—Sn phase superconducting wire according to the embodiment 1 of the invention in relation to the ratio of the boundary region of the ε-phase bronze layer formed when a Nb₃Sn superconducting wire is produced from the precursor wire by heat-treatment;

FIG. 4 is a cross-sectional view of a composite billet according to the embodiment 2 of the invention; and

FIG. 5 is a graph illustrating the J_{c} property measured in a magnetic field of 12 T in liquid helium and Qₕ property measured in a magnetic field for ±3 T cycle in liquid helium of the precursor wire of the Nb—Sn phase superconducting wire according to the embodiment 2 of the invention in relation to the ratio of the boundary region of the ε-phase bronze layer formed when a Nb₃Sn superconducting wire is produced from the precursor wire by heat-treatment.

### DESCRIPTION OF THE PREFERRED EMBODIMENTS

Embodiment 1

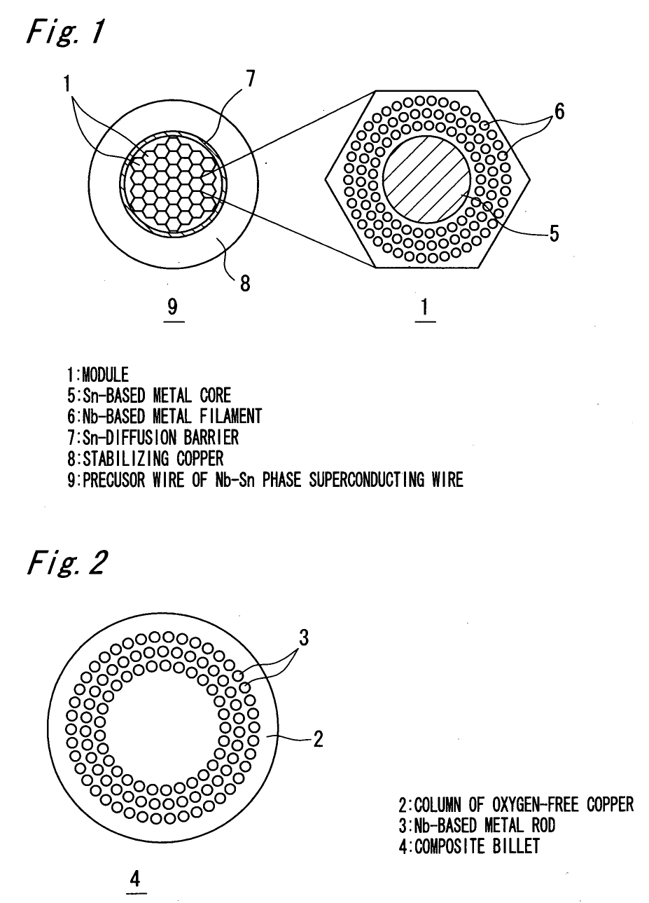

FIG. 1 shows a cross-sectional view of a precursor wire of a Nb—Sn phase superconducting wire according to an embodiment 1 and FIG. 2 shows a cross-sectional view of a composite billet for producing a module 1 of the above-mentioned precursor wire according to the embodiment 1.

In the production of the composite billet 4 of the embodiment 1, 106 holes in total are formed in three rows concentrically in an oxygen-free copper column 2 with a diameter of 140 mm in a region from a radius of 35 mm to 51 mm from the center of the column. Nb-based metal rods 3 with a diameter of 6 mm are packed in the respective holes formed to obtain the composite billet 4. The above-mentioned Nb-based metal rods are to be the Nb-based metal filaments 6 in a precursor wire of a Nb—Sn phase superconducting wire to be obtained finally. The obtained composite billet 4 is extrusion-processed to reduce the diameter to 50 mm and the unnecessary copper material in the outer circumference is removed.

Further, a hole is formed in the copper portion in the center part and a Sn-based metal rod to be a Sn-based metal core 5 is inserted into the hole. It is noted that the copper column may be referred to as matrix. Then, the Nb-based metal filaments 6 and copper matrix may be referred to as shell surrounding of the core.

The boundary position of the ε-phase bronze layer to be formed at the time of heat-treatment of the precursor wire to be obtained finally is determined depending on the diameter of the Sn-based metal rod and the volume ratio x of the ε-phase bronze layer region to be formed in the Cu-based metal matrix is calculated according to the following equation (1):

$$\begin{matrix}x = ( volume of ɛ \text{-} phase bronze layer region ) \div \\ ( volume of Cu \text{-} based metal matrix ) \\ = ( moles of Sn ) \times 3 \div ( moles of Cu ) \\ = 3 \times ( density of Sn ) \times ( volume ratio of Sn occupying in module ) \div \\ ( atomic weight of Sn ) \div \{ ( density of Cu ) \times \\ ( volume ratio of occupying in module ) \div ( atomic weight of Cu ) \} .\end{matrix} \qquad ( 1 )$$

In the embodiment 1, the diameter of the Sn-based metal rod is changed to be (a) 16.9 mm, (b) 19.1 mm, (c) 19.8 mm, (d) 20.5 mm, (e) 20.9 mm, (f) 21.2 mm, (g) 21.9 mm, and (h) 23.4 mm. Accordingly, the ratio of the ε-phase bronze layer to the Cu-based metal matrix is changed to be (a) 0.34, (b) 0.47, (c) 0.51, (d) 0.58, (e) 0.62, (f) 0.67, (g) 0.71, and (h) 0.80.

After extrusion process, the composite billet 4 into which the Sn-based metal rod is inserted is reduced in the diameter by drawing process and further machined to be a hexagonal rod with 4 mm of the opposite side length and thus obtain a Cu/Nb/Sn composite rod for a module. The Cu/Nb/Sn composite rod is cut and 37 rods are bundled and the bundled composite rods are surrounded with a Ta tube to be a Sn diffusion barrier 7 and further the outer circumference of the Ta tube 7 is surrounded with a 7.5 mm-thick oxygen-free copper tube to be a copper stabilizer 8. The Cu/Nb/Sn composite rod combined with the Ta tube and the oxygen-free copper tube is drawn to 0.5 mm diameter to obtain a precursor wire 9 of a Nb—Sn phase superconducting wire.

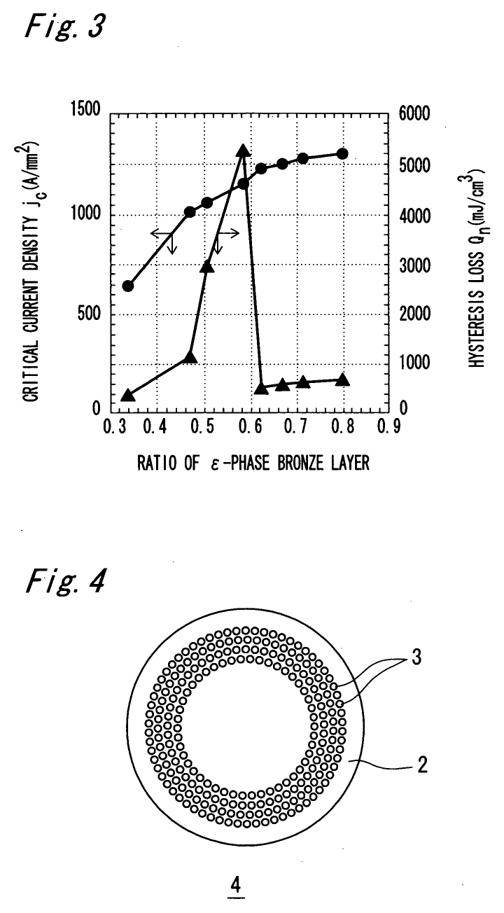

A sample for measurement is cut out of the obtained precursor wire and heat-treated at 650° C. for 10 days in an inert gas atmosphere to obtain a Nb₃Sn superconducting wire. The J_{c} and the Qₕ of the obtained superconducting wire are measured in a magnetic field of 12 T in liquid helium and in a magnetic field for ±3 T cycle in liquid helium, respectively. FIG. 3 shows the size dependence of the above-mentioned Sn-based metal rod on the J_{c} and the Qₕ properties. Here, when the ratio x of the ε-phase bronze layer region is 0.6 or higher, the boundary region of the ε-phase bronze layer is in the outside of the region where the Nb-based metal filaments 6 exist. In other words, in the module 1 comprising the Nb-based metal filaments 6 and the Sn-based metal cores 5 embedded in the Cu-based metal matrix, the Nb-based metal filaments 6 exist only in the ε-phase bronze layer region. As shown in FIG. 3, if the ratio x of the ε-phase bronze layer region is adjusted to be approximately not lower than 0.6 and not more than 0.8, preferably not lower than 0.62 and not more than 0.78, a precursor wire of a Nb—Sn phase superconducting wire having a high J_{c} property and a low Qₕ property can be obtained.

On the other hand, when the ratio x of the ε-phase bronze layer region is lower than 0.6, that is, the boundary region of the ε-phase bronze layer to be formed in the Cu-based metal matrix during the heat-treatment of the precursor wire at 300 to 600° C. enters in the inside of the Nb-based metal filaments 6 region, it is impossible to suppress the increase of Qₕ property like the case of the embodiment 1 because the mutual contact of Nb₃Sn filaments which is a cause of increase of Qₕ property occurs. Further, when the ratio x of the ε-phase bronze layer region is about 0.3, that is, the boundary region of the ε-phase bronze layer is in the inside of the Nb-based metal filaments 6 region, it is impossible to obtain such a high J_{c} property as described above, although the Qₕ decreases, because the amount of Nb₃Sn generated by heat-treatment is decreased by decreasing the volume ratio of the Sn-based metal cores 5. On the contrary, when the ratio x of the ε-phase bronze layer region is higher than 0.8, it is impossible to obtain the precursor wire because the Sn-based metal rod in the composite billet 4 enters in the inside of the Nb-based metal filaments region.

In the embodiment 1, the diameter of the Nb-based metal rod 3 of the composite billet 4 is adjusted to be 6 mm and the number of the holes is set to be 106, and in the finally obtained precursor wire, the diameter of the Nb-based metal filaments 6 becomes 3 μm, the intervals of the Nb-based metal filaments 6 become 0.9 μm, and the volume ratio of the Nb-based metal filaments 6 in the module 1 becomes 0.32. The size and the number of the above-mentioned Nb-based metal rod 3 can be changed within permissible limits of the wire design depending on the required J_{c} property and Qₕ property. In case of the superconducting wire having high J_{c} and low Qₕ properties required for a large scale superconducting coil used for nuclear fusion, the volume ratio of the Nb-based metal filaments 6 in the module 1 is approximately not lower than 0.28 and not more than 0.34 and preferably not lower than 0.30 and not more than 0.33; the diameter of the Nb-based metal filaments 6 is approximately not thinner than 1 μm and not thicker than 5 μm and preferably approximately not thinner than 2.0 μm and not thicker than 3.5 μm; and the intervals of the Nb-based metal filaments 6 are approximately not narrower than 0.7 μm and not wider than 1.5 μm and preferably approximately not narrower than 0.8 μm and not wider than 1.2 μm.

When the volume ratio of the Nb-based metal filaments 6 in the module 1 is lower than 0.28,it is impossible to obtain such a J_{c} property as described above because the amount of the Nb₃Sn to be produced finally by reaction of the Nb-based metal filaments 6 and the Sn-based metal cores 5 by the heat-treatment decreases. In addition, the boundary region of the ε-phase bronze layer to be produced in the matrix during the heat-treatment of the precursor wire at 300 to 600° C. enters in the inside of the Nb-based metal filaments 6 region, it is impossible to suppress the increase of Qₕ property like the case of the embodiment 1 because the mutual contact of Nb₃Sn filaments which is a cause of increase of Qₕ property occurs. On the contrary, when the volume ratio of the Nb-based metal filaments 6 in the module 1 is higher than 0.34, the intervals of the Nb-based metal filaments 6 cannot be kept sufficiently, it is impossible to suppress the increase of Qₕ property like the case of the embodiment 1 because the mutual contact of Nb₃Sn filaments which is a cause of increase of Qₕ property occurs.

Further, when the diameter of the Nb-based metal filaments 6 in the module 1 is thinner than 1 μm, a high J_{c} property like the case of the embodiment 1 cannot be obtained because it is highly possible that parts of the filaments are broken. On the contrary, when the diameter of the Nb-based metal filaments 6 in the module 1 is thicker than 5 μm, it is impossible to obtain high J_{c} property like the case of the embodiment 1 because the filaments cannot necessarily be reacted entirely by the heat-treatment and the amount of Nb₃Sn generated by heat-treatment is decreased.

Further, when the intervals of the Nb-based metal filaments 6 in the module 1 are narrower than 0.7 μm, it is impossible to suppress the increase of Qₕ property like the case of the embodiment 1 because the mutual contact of Nb₃Sn filaments which is a cause of increase of Qₕ property occurs. On the contrary, when the intervals of the Nb-based metal filaments 6 in the module 1 are wider than 1.5 μm, it is impossible to obtain high J_{c} property because the amount of Nb₃Sn generated by heat-treatment is decreased.

Although as a diffusion barrier material of Sn, the Ta tube is used in the embodiment 1, for example, a Ta plate which is machined to be tubular can cause similar effects to those in the embodiment 1. Also, although Ta is used as the material of the diffusion barrier of Sn, any metals such as Nb-based metal which are effective to prevent diffusion of Sn can cause similar effects to those in the embodiment 1.

Embodiment 2

FIG. 4 shows a cross-sectional view of a composite billet 4 for producing a module 1 of a precursor wire according to the embodiment 2. In FIG. 4, those assigned with the same symbols as in FIG. 2 are same or equivalent materials and parts.

In the production of the composite billet 4 of the embodiment 2, 224 holes in total are formed in four rows concentrically in an oxygen-free copper column 2 with a diameter of 140 mm in a region from a radius of 37 mm to 52 mm from the center of the column. Nb-based metal rods 3 with a diameter of 3.7 mm are packed in the respective holes formed to obtain the composite billet 4. The obtained billet 4 is extrusion-processed to reduce the diameter to 50 mm similarly to that in the embodiment 1 and the unnecessary copper material in the outer circumference is removed. Further, a hole is formed in the copper portion in the center part and a Sn-based metal rod to be a Sn-based metal core 5 is inserted into the hole.

The boundary position of the ε-phase bronze layer to be formed at the time of heat-treatment of the precursor wire to be obtained finally is determined depending on the diameter of the Sn-based metal rod and the volume ratio x of the ε-phase bronze layer region to be formed in the Cu-based metal matrix is calculated similarly to that in the embodiment 1. In the embodiment 2, the diameter of the Sn-based metal rod is changed to be (a) 16.4 mm, (b) 18.4 mm, (c) 19.4 mm, (d) 20.0 mm, (e) 20.5 mm, (f) 21.2 mm, (g) 21.9 mm, and (h) 22.6 mm, respectively. Accordingly, the ratio of the ε-phase bronze layer to the Cu-based metal matrix is changed to be (a) 0.28, (b) 0.37, (c) 0.42, (d) 0.47, (e) 0.51, (f) 0.52, (g) 0.56, and (h) 0.60, respectively.

After extrusion process, the composite billet 4 into which the Sn-based metal core rod is inserted is reduced in the diameter by drawing process in the same manner as the embodiment 1 and further machined to be a hexagonal rod with 5.4 mm length of the opposite side and thus obtain a Cu/Nb/Sn composite rod for a module. The Cu/Nb/Sn composite rod is cut and 19 rods are bundled and the bundled composite rods are surrounded with a Ta tube to be a Sn diffusion barrier 7 and further the outer circumference of the Ta tube 7 is surrounded with a 7.5 mm-thick oxygen-free copper tube to be a copper stabilizer 8 in the same manner as the embodiment 1. The Cu/Nb/Sn composite rod combined with the Ta tube and the oxygen-free copper tube is drawn to 0.5 mm diameter to obtain a precursor wire 9 of a Nb—Sn phase superconducting wire.

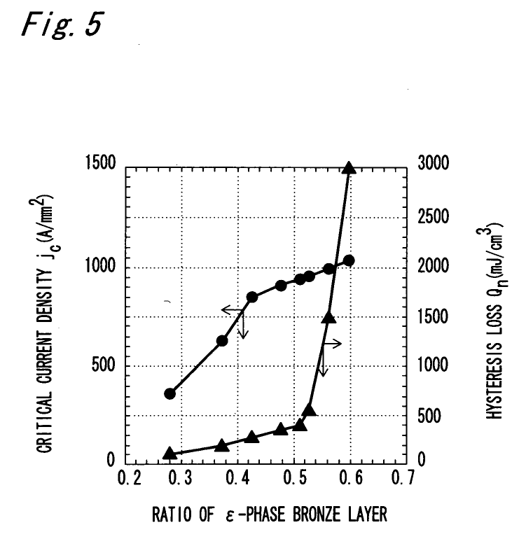

A sample for measurement is cut out of the obtained precursor wire and, similarly to the case of the embodiment 1, heat-treated at 650° C. for 10 days in an inert gas atmosphere to obtain a Nb₃Sn superconducting wire. The J_{c} and the Qₕ of the obtained superconducting wire are measured in a magnetic field of 12 T in liquid helium and in a magnetic field for ±3 T cycle in liquid helium, respectively. FIG. 5 shows the size dependence of the above-mentioned Sn-based metal rod on the J_{c} and the Qₕ properties. Here, when the ratio x of the ε-phase bronze layer region is 0.4, the ratio of the Nb-based metal filaments 6 existing in the boundary region of the ε-phase bronze layer is 0.08. Also in the ratio x of the ε-phase bronze layer region is 0.55, the ratio of the Nb-based metal filaments 6 existing in the boundary region of the ε-phase bronze layer is 0.32. As shown in FIG. 5, if the ratio x of the ε-phase bronze layer region is adjusted to be approximately not lower than 0.4 and not more than 0.55, preferably not lower than 0.45 and not more than 0.52, a precursor wire of a Nb—Sn phase superconducting wire having a low Qₕ property and suppressed decrease of J_{c} property can be obtained.

On the other hand, when the ratio x of the ε-phase bronze layer region is lower than 0.4, that is, the boundary region of the ε-phase bronze layer to be formed in the Cu-based metal matrix during the heat-treatment of the precursor wire at 300 to 600° C. enters in the inside of the Nb-based metal filaments 6 region, it is impossible to obtain a high J_{c} property, although the Qₕ decreases, because the amount of Nb₃Sn generated by heat-treatment is decreased by decreasing the volume ratio of the Sn-based metal cores 5. Further, when the ratio x of the ε-phase bronze layer region is higher than 0.55, it is impossible to suppress the increase of Qₕ property because the mutual contact of the Nb₃Sn filaments which is a cause of increase of Qₕ property occurs in wide region.

In the embodiment 2, the diameter of the Nb-based metal rod 3 of the composite billet 4 is adjusted to be 3.7 mm and the number of the holes is set to be 224, and in the finally obtained precursor wire, the diameter of the Nb-based metal filaments 6 becomes 2.6 μm, the intervals of the Nb-based metal filaments 6 become 0.9 μm, and the volume ratio of the Nb-based metal filaments 6 in the module 1 become 0.25. The size and the number of the above-mentioned Nb-based metal rod 3 can be changed within permissible limits of the wire design depending on the required J_{c} and Qₕ properties. In case of the superconducting wire having high J_{c} and low Qₕ properties required for a large scale superconducting coil used for nuclear fusion, the volume ratio of the Nb-based metal filaments 6 in the module 1 is approximately not lower than 0.23 and not more than 0.27 and preferably approximately not lower than 0.24 and not more than 0.26; the diameter of the Nb-based metal filaments 6 is approximately not thinner than 1 μm and not thicker than 5 μm and preferably approximately not thinner than 2.0 μm and not thicker than 3.5 μm; and the intervals of the Nb-based metal filaments 6 are approximately not narrower than 0.7 μm and not wider than 1.5 μm and preferably approximately not narrower than 0.8 μm and not wider than 1.2 μm.

When the volume ratio of the Nb-based metal filaments 6 in the module 1 is lower than 0.23, it is impossible to obtain a high J_{c} property because the amount of the Nb₃Sn to be produced finally by reaction of the Nb-based metal filaments 6 and the Sn-based metal cores 5 by the heat-treatment decreases. On the contrary, when the volume ratio of the Nb-based metal filaments 6 in the module 1 is higher than 0.27, the boundary region of the ε-phase bronze layer produced by the heat-treatment enters in the inside of the Nb-based metal filaments 6 region and the intervals of the Nb-based metal filaments 6 cannot be kept sufficiently. Therefore, it is impossible to suppress the increase of Qₕ property like the case of the embodiment 2 because the mutual contact of Nb₃Sn filaments which is a cause of increase of Qₕ property occurs.

Further, when the diameter of the Nb-based metal filaments 6 in the module 1 is thinner than 1 μm, a high J_{c} property like the case of the embodiment 2 cannot be obtained because it is highly possible that parts of the filaments are broken. On the contrary, when the diameter of the Nb-based metal filaments 6 in the module 1 is thicker than 5 μm, it is impossible to obtain high J_{c} property like the case of the embodiment 2 because the filaments cannot necessarily be reacted entirely by the heat-treatment and the amount of Nb₃Sn generated by heat-treatment is decreased.

Further, when the intervals of the Nb-based metal filaments 6 in the module 1 are narrower than 0.7 μm, it is impossible to suppress the increase of Qₕ property because the mutual contact of Nb₃Sn filaments which is a cause of increase of Qₕ property occurs. On the contrary, when the intervals of the Nb-based metal filaments 6 in the module 1 are wider than 1.5 μm, it is impossible to obtain high J_{c} property because the amount of Nb₃Sn generated by heat-treatment is decreased.

Although as a diffusion barrier material of Sn, the Ta tube is used in the embodiment 2, for example, a Ta plate which is machined to be tubular can cause similar effects to those in the embodiment 2. Also, although Ta is used as the material of the diffusion barrier of Sn, any metals such as Nb-based metal which are effective to prevent diffusion of Sn can cause similar effects to those in the embodiment 2.

In this invention, the Cu-based metal means pure Cu or Cu containing about 2% by weight or less of Sn.

Also, the Nb-based metal means pure Nb or Nb containing at least one of about 10% by weight or less of Ta and about 5% by weight or less of Ti.

Further, the Sn-based metal means pure Sn or Sn containing at least one of about 5% by weight or less of Ti, about 2% by weight or less of Cu, and about 2% by weight or less of In.

Although the present invention has been described in connection with the preferred embodiments thereof with reference to the accompanying drawings, it is to be noted that various changes and modifications are apparent to those skilled in the art. Such changes and modifications are to be understood as included within the scope of the present invention as defined by the appended claims, unless they depart therefrom.

What is claimed is:

1. A precursor wire of a Nb—Sn phase superconducting wire, the precursor wire being heat-treated to produce the superconducting wire, and elongating in the longitudinal direction, the precursor wire comprising a plurality of modules having a cross section including a core part and a shell part surrounding of the core part, wherein each of modules comprises:
a core part made of only Sn-based metal; and
a shell part including:
a matrix made of a Cu-based metal; and
Nb-based metal filaments embedded in the Cu-based metal,
wherein the Nb-based metal filaments are arranged at equal intervals concentrically around the core part and further around the circumferences of Nb-based metal filaments sequentially toward the outer circumference, and
wherein, in each of modules, the amount of the Sn-based metal of the core part is so adjusted as to form an area defined by the boundaries of the ε-phase bronze layers, which are formed in the module by reaction of the Sn-based metal of the core part and Cu-based metal of the matrix by the heat-treatment, so that the area includes all of the Nb-based metal filaments in the module.

2. The precursor wire of the Nb—Sn phase superconducting wire according to claim 1, wherein each of the modules satisfies as follows:
the volume ratio of the Nb-based metal filaments occupying in each of the modules is approximately not lower than 0.28 and not more than 0.34;
the volume ratio of the ε-phase bronze layer to the Cu-based metal matrix in each module is approximately not lower than 0.6 and not more than 0.8;
the diameter of the Nb-based metal filament is approximately not thinner than 1 μm and not thicker than 5 μm; and
the intervals of the Nb-based metal filaments are approximately not narrower than 0.7 μm and not wider than 1.5 μm.

3. A precursor wire of a Nb—Sn phase superconducting wire, the precursor wire being heat-treated to produce the superconducting wire, and elongating in the longitudinal direction, the precursor wire comprising a plurality of modules having a cross section including a core part and a shell part surrounding of the core part, wherein each of modules comprises:
a core part made of only Sn-based metal; and
a shell part including:
a matrix made of a Cu-based metal; and
Nb-based metal filaments embedded in the Cu-based metal,
wherein the Nb-based metal filaments are arranged at equal intervals concentrically around the core part and further around the circumferences of Nb-based metal filaments sequentially toward the outer circumference, and
wherein, in each of modules, the amount of the Sn-based metal of the core part is so adjusted as to form an area defined by the boundaries of the ε-phase bronze layers, which are formed in the module by reaction of the Sn-based metal of the core part and Cu-based metal of the matrix by the heat-treatment, so that the area includes a ratio of approximately not lower than 0.08 and not more than 0.32 of the existence region of the Nb-based metal filaments in the module.

4. A precursor wire of the Nb—Sn phase superconducting wire according to claim 3, wherein each of the modules satisfies as follows:
the volume ratio of the Nb-based metal filaments occupying in each of the modules is approximately not lower than 0.23 and not more than 0.27;
the volume ratio of the ε-phase bronze layer to the Cu-based metal matrix in each module is approximately not lower than 0.4 and not more than 0.55;
the diameter of the Nb-based metal filament is approximately not thinner than 1 μm and not thicker than 5 μm; and
the intervals of the Nb-based metal filaments are approximately not narrower than 0.7 μm and not wider than 1.5 μm.
